(19) United States
(12) Patent Application Publication
(10) Pub. No.: US 2013/0094154 A1
(43) Pub. Date: Apr. 18, 2013

(54) POWER SUPPLY DEVICE

(71) Applicant: Yu-Cheng SHEN, Taipei (TW)

(72) Inventor: Yu-Cheng SHEN, Taipei (TW)

(21) Appl. No.: 13/608,383

(22) Filed: Sep. 10, 2012

(30) Foreign Application Priority Data
Oct. 18, 2011 (TW) 100137790

(51) Int. Cl. H05K 7/10

(52) U.S. Cl. 361/731

(57) ABSTRACT

A power supply device includes a power input module and a power functional module. The power input module has a power connecting unit and a power converting unit, which has a first connecting part. The power functional module comprises a functional unit or a plurality of functional units which connect with each other. The power input module is detachably coupled with the power functional modules of different assembling types, so that the power supply device can be transformed into various application modes. Accordingly, the power supply device can satisfy multiple applications and uses.

### CROSS REFERENCE TO RELATED APPLICATIONS

This Non-provisional application claims priority under 35 U.S.C. §119(a) on Patent Application No(s). 100137790 filed in Taiwan, Republic of China on Oct. 18, 2011, the entire contents of which are hereby incorporated by reference.

### BACKGROUND OF THE INVENTION

1. Field of Invention

The present disclosure relates to a power supply device and, in particular, to a power supply device with a multi-functional structure.

2. Related Art

According to the rapid development and progress of electronic technology, many consuming electronic products, which are user-friendly, have been provided to make our lives more convenient.

Therefore, a user may own many kinds of electronic products, such as cell phone, laptop, MP3 player, and the likes, at the same time. Most electronic products have corresponding specific power supply devices (adaptors). The more electronic products one user owns, the more power supply devices he/she certainly needs. Thus, the user also needs a larger space for storing and sorting the power supply devices.

Therefore, it is an important subject to provide a power supply device that can be applied to various electronic products so that the user can operate them conveniently and the storage space can be minimized.

### SUMMARY OF THE INVENTION

The present disclosure is to provide a power supply device that can perform multiple functions, and can be applied to various kinds of power sources and electronic products and convenient in operation and storage.

A power supply device comprises a power input module and a power functional module. The power input module has a power connecting unit and a power converting unit. A first connecting part is configured at one side of the power converting unit, and the power connecting unit is detachably coupled with the power converting unit. The power functional module comprises at least a functional unit, which has a second connecting part for electrically connecting with the first connecting part. The functional unit is detachably coupled with the power converting unit.

In one embodiment, the power connecting unit is a two-pin plug, a three-pin plug, or a car charger adapter.

In one embodiment, the power connecting unit has a receiving part, the power converting unit has a locking part, and the power connecting unit and the power converting unit are coupled as the receiving part is connected to the locking part.

In one embodiment, the first connecting part has a plurality of contact elements, the second connecting part has a plurality of contact parts corresponding to the contact elements, and the contact elements contact against the corresponding contact parts.

In one embodiment, the power converting unit has a locking slot, the function unit has a locking rail, and the locking slot is coupled with the locking rail.

In one embodiment, the power converting unit is an AC/DC power converting element or a DC/DC power converting element.

In one embodiment, the functional unit of the power functional module comprises one or any combinations of a DC voltage output element, a rechargeable battery, an USB connector, a light-emitting element, a stun rod and a DC fan.

In one embodiment, when the functional unit is a rechargeable battery, the functional unit further has a third connecting part.

In one embodiment, the third connecting part comprises a plurality of contact elements, which are metal slices.

As mentioned above, the functional unit and power connecting unit of the power supply device of this disclosure are detachably coupled with the power converting unit, so that it is possible to select one of different aspects of power connecting units in accordance with a specific socket. In addition, the power supply device of the disclosure can be applied to various kinds of electronic products or perform multiple functions (e.g. charging, illuminating, or power supplying) by changing the functional unit. Compared with the conventional art, the power supply device of the disclosure can correspond to various kinds of input power sources, electronic products and functions, so that it is convenient for the user to operate and store the power supply device.

These and other features, aspects and advantages of the present invention will become better understood with regard to the following description, appended claims, and accompanying drawings.

### BRIEF DESCRIPTION OF THE DRAWINGS

FIG. 1 is a schematic diagram showing a power supply device of an embodiment;

FIGS. 2A and 2B are schematic diagrams showing the separated parts of the power supply device of FIG. 1;

FIGS. 3A to 3C are schematic diagrams showing several aspects of the power connecting unit;

FIGS. 4A to 4C are schematic diagrams showing several aspects of the functional unit; and

FIG. 5 is a schematic diagram showing a power supply device of another aspect.

### DETAILED DESCRIPTION OF THE INVENTION

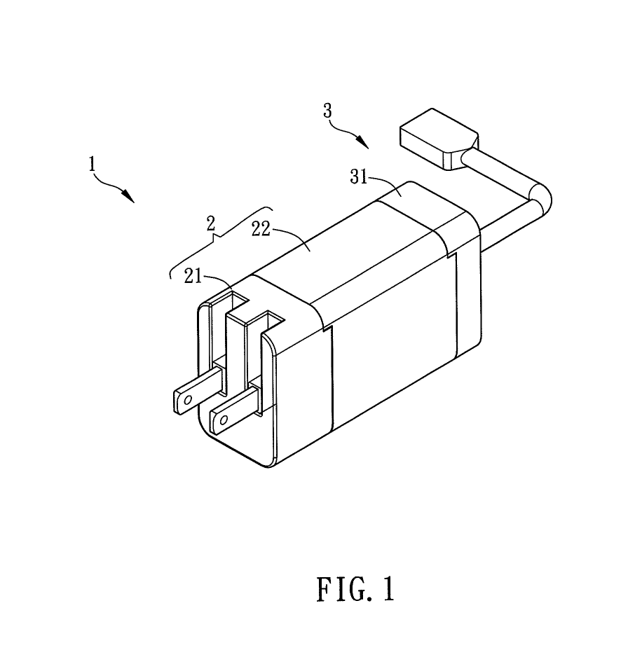

FIG. 1 is a schematic diagram showing a power supply device 1 according to an embodiment of the present disclosure. The power supply device 1 comprises a power input module 2 and a power functional module 3. The appearance of the power supply device 1 is rectangular for example. Of course, the appearance of the power supply device 1 of this disclosure is not limited to this, and it may be any shape that is easily held and operated, such as cylinder, square or the likes.

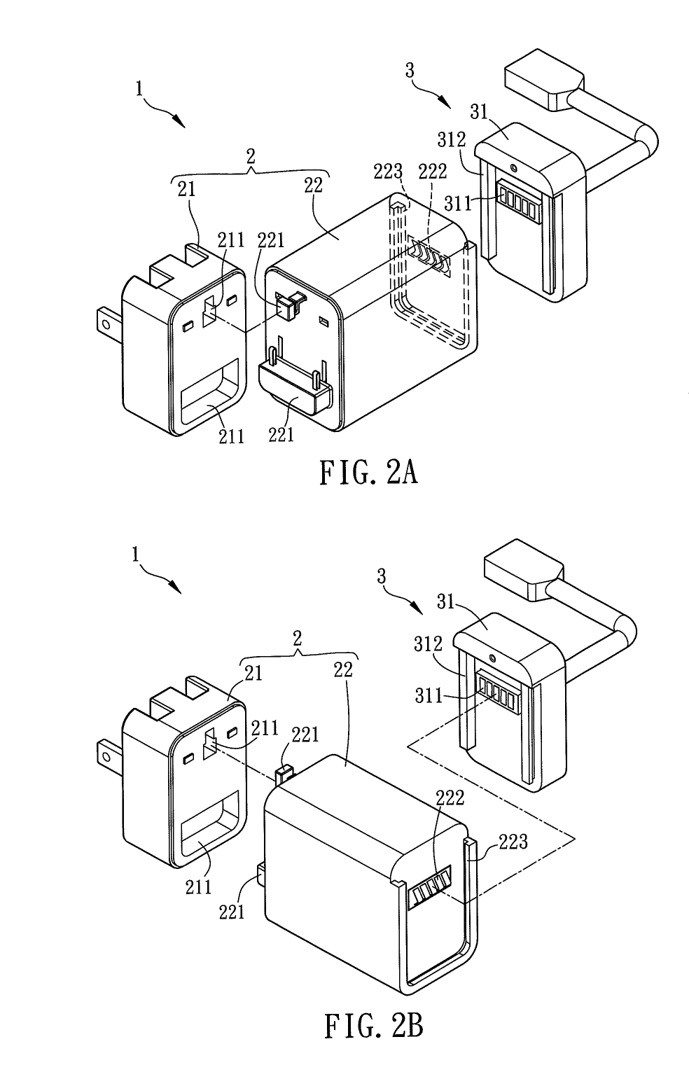

The power supply device 1 will be further illustrated with reference to FIGS. 2A and 2B. FIGS. 2A and 2B are schematic diagrams showing the separated parts of the power supply device 1 of FIG. 1. The power input module 2 has a power connecting unit 21 and a power converting unit 22. The power connecting unit 21 is detachably coupled with the power converting unit 22.

In one embodiment, the power connecting unit 21 has a receiving part 211, and the power converting unit 22 has a locking part 221. When the receiving part 211 and the locking part 221 are connected, the power connecting unit 21 can be coupled with the power converting unit 22. In this case, for example, the receiving part 211 is a recess, while the locking part 221 is a protruding hook. Alternatively, in other embodiments, the power connecting unit is configured with a locking part, while the power converting unit is configured with a receiving part, which is coupled with the locking part. In order to enhance the coupling effect, the power connecting unit 21 and the power converting unit 22 may be configured with a plurality of receiving parts 211 and a plurality of locking parts 221, respectively. In this embodiment, the power connecting unit 21 has two receiving parts 211, and the power converting unit 22 has two locking parts 221. The receiving parts 211 are configured corresponding to the locking parts 221.

To be noted, except for the function of connecting the power connecting unit 21 and the power converting unit 22, the receiving parts 211 and the locking parts 221 may further be configured with corresponding conductive elements, respectively, which can connect to each other. When the power connecting unit 21 is inserted into a general socket, power can be transmitted to the power converting unit 22 through the receiving part(s) 211 and the locking part(s) 221. However, in practice, it is unnecessary to use all of the receiving parts 211 and the locking parts 221 for transmitting power. In some cases, depending on the demands of products and designs, only at least one receiving part 211 and at least one locking part 221 are electrically connected for transmitting power, while the residual receiving parts 211 and locking parts 221 are configured for connection only.

The power converting unit 22 has a first connecting part 222. In addition, the power functional module 3 comprises one or more functional units 31, which can connect to each other. The functional units 31 are detachably coupled with the power converting unit 22. Each functional unit 31 has a second connecting part 311 for electrically connecting with the first connecting part 222, so that the power converting unit 22 can be coupled with the functional unit 31. To be noted, the first connecting parts 222 and the second connecting parts 311 are correspondingly disposed, so that they can be electrically connected to each other. Besides, the first connecting parts 222 and the second connecting parts 311 may further be configured with corresponding conductive elements, such as metals or other conductive materials.

For example, the first connecting parts 222 and the second connecting parts 311 are configured with a plurality of contact elements and a plurality of contact parts, respectively. In this embodiment, the contact element is a metal slice, while the contact part is a metal conductive plate. The contact element can contact against the corresponding contact part by the inherent elastic force when the power converting unit 22 is coupled with the functional unit 31, thereby firmly and electrically connecting the first connecting part 222 with the second connecting parts 311. In this disclosure, the numbers and positions of the contact elements and the contact parts are not limited to this example. For example, the contact parts may be disposed on the first connecting part, while the contact elements are disposed on the second connecting part.

In order to enhance the connection between the power converting unit 22 and the functional unit 31, the power converting unit 22 may further have a locking slot 223, and the functional unit 31 may further have a locking rail 312, which can slide into and thus connect to the locking slot 223. The locking slot 223 is disposed on the power converting unit 22. In this embodiment, the locking slot 223 is U-shaped, and a recess is formed between the locking slot 223 and the power converting unit 22, so that the cross-section of a part of the locking slot 223 is L-shaped. The locking rails 312 are disposed at two sides of the functional unit 31 and are respectively an L-shaped hook body corresponding to the appearance of the locking slot 223. The locking rails 312 are arranged as the back-to-back L-shaped hook bodies at two sides of the functional unit 31. The size and shape of the locking rail 312 are cooperated with that of the locking slot 223. Thus, when the locking rail 312 slides and inserts into the locking slot 223, the relative position between the power converting unit 22 and the functional unit 31 can be firmly fixed. In addition, the shapes and sizes of the locking slot 223 and the locking rail 312 of the present disclosure are not limited to this embodiment, and can be designed based on the actual needs.

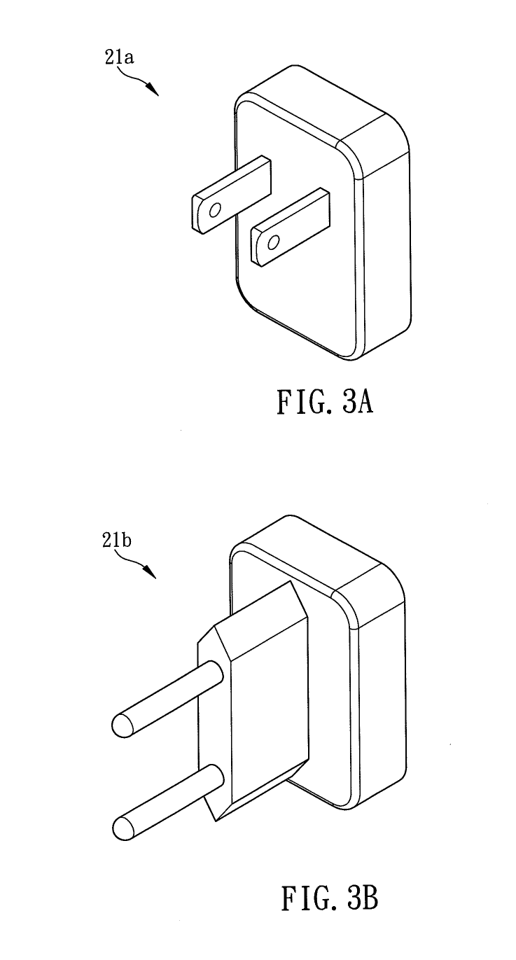

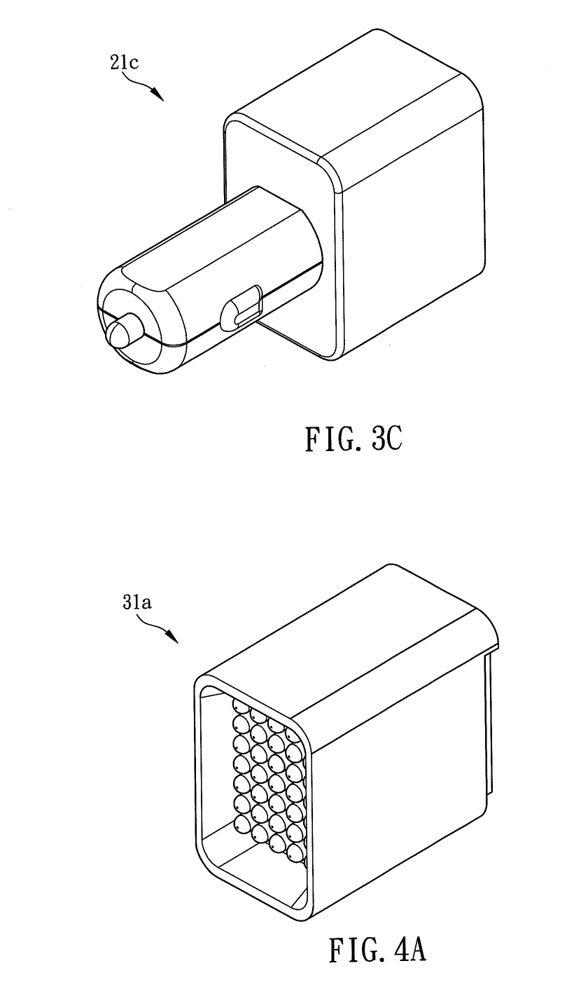

FIGS. 3A to 3C are schematic diagrams showing several aspects of the power connecting unit. Referring to FIG. 1 in view of FIGS. 3A to 3C, the power connecting unit 21 can be a two-pin plug, a three-pin plug, or a car charger adapter. In this embodiment, the power connecting unit 21 is, for example but not limited to, a two-pin flat plug that can be folded and stored. In practice, the power connecting unit 21 may have various aspects depending on different demands. For example, three different structure aspects of the power connecting unit 21 will be described hereinafter with reference to FIGS. 3A to 3C, respectively.

Different aspects of the power connecting unit 21 can be selected and used for matching different sockets or the local frequencies and voltages. For example, the power connecting unit may be a two-pin flat plug (as the power connecting unit 21a of FIG. 3A), a 2 flat-pin+1 round-pin plug, a three-pin flat plug, a two-pin plug with non-parallel pins, two round-pin plug (as the power connecting unit 21b of FIG. 3B), or a car charger adapter (as the power connecting unit 21c of FIG. 3C).

Referring to FIG. 2A again, the power converting unit 22 may be a DC-to-DC power converting element or an AC-to-DC power converting element. In this embodiment, the power converting unit 22 is, for example, an AC-to-DC power converting element. After receiving the power source, the power converting unit 22 can convert it to the voltage fitting the power functional module 3. For example, the power converting unit 22 can convert the 120V AC voltage into the 5V DC voltage, which is then transmitted from the power converting unit 22 to the functional unit 31 through the first connecting part 222 and the second connecting part 311.

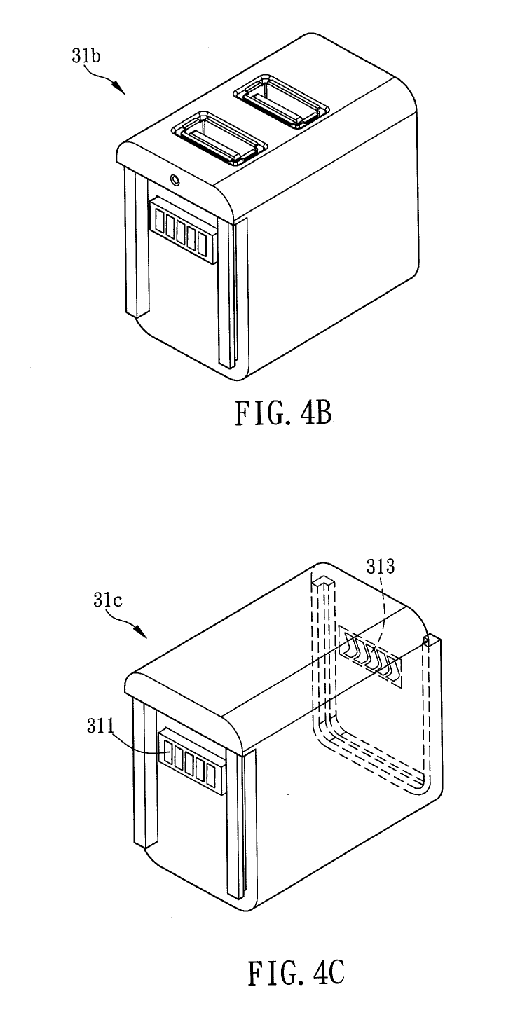

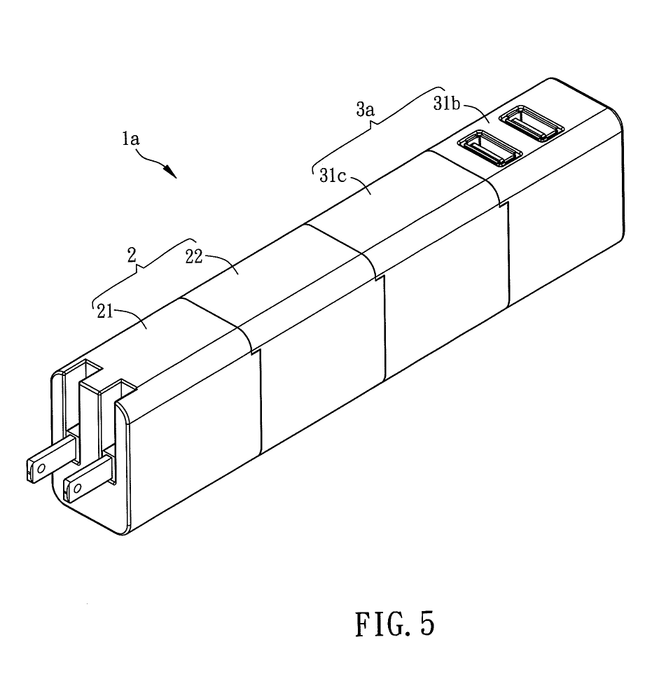

FIGS. 4A to 4C are schematic diagrams showing several aspects of the functional unit 31. The functional unit 31 is, for example but not limited to, a DC voltage outputting element. The functional unit 31 may have various aspects depending on the applied electronic products. For example, the functional unit 31 can be a light-emitting element (as the functional unit 31a of FIG. 4A), a single-hole/multiple-hole USB connector (as the functional unit 31b of FIG. 4B), a stun rod, a DC fan, or a rechargeable battery (as the functional unit 31c of FIG. 4C). As mentioned above, the light-emitting element may include an LED, a CCFL, or a lamp.

To be noted, as shown in FIG. 4C, when the functional unit 31c is a rechargeable battery, a second connecting part 311 is disposed at one side of the functional unit 31c, and a third connecting part 313 is disposed at the other side of the functional unit 31c.

In this embodiment, the second connecting part 311 comprises a plurality of contact parts disposed in a row, and the third connecting part 313 comprises a plurality of contact elements respectively corresponding to the contact parts. Accordingly, the functional unit 31c used as a rechargeable battery can electrically connected to the second connecting part 311 of another functional unit 31 through its third connecting part 313 for providing power to another functional unit 31. The numbers and positions of the contact elements and contact parts of the present disclosure are not limited to this embodiment. The contact elements can contact against the corresponding contact parts by their elastic forces as the functional unit 31c is connected with other functional unit or power converting unit, thereby providing firmly electrical connection. In some embodiments, if the second connecting part has a plurality of contact elements, the third connecting part may have a plurality of contact parts corresponding to the contact elements. In addition, the power converting unit can transmit power source to the functional unit 31c (rechargeable battery) for charging the functional unit 31c.

FIG. 5 is a schematic diagram showing a power supply device 1a of another aspect. Compared with the power supply device 1, the power functional module 3a of the power supply device 1a has two functional units 31b and 31c coupling to each other. The functional unit 31c coupled to the power converting unit 22 is a rechargeable battery, and the other functional unit can be a rechargeable battery, a DC voltage output element, a light-emitting element, a stun rod, a DC fan, or a single-hole/multiple-hole USB connector. To be noted, the other functional unit 31b of this embodiment is, for example but not limited to, a multiple-hole USB connector.

In summary, the functional unit and power connecting unit of the power supply device of this disclosure are detachably coupled with the power converting unit, so that it is possible to select one of different aspects of power connecting units in accordance with a specific socket. In addition, the power supply device of the disclosure can be applied to various kinds of electronic products or perform multiple functions (e.g. charging, illuminating, or power supplying) by changing the functional units. Compared with the conventional art, the power supply device of the disclosure can correspond to various kinds of input power sources, electronic products and functions, so that the user can select and connect different types of power connecting units and functional units for operation according to the actual demand. Thus, it is convenient for the user to operate and store the power supply device, and the number of the power supply devices can be reduced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A power supply device, comprising:
a power input module having a power connecting unit and a power converting unit, wherein a first connecting part is configured at one side of the power converting unit, and the power connecting unit is detachably coupled with the power converting unit; and
a power functional module comprising at least a functional unit, wherein the functional unit has a second connecting part for electrically connecting with the first connecting part;
wherein, the functional unit is detachably coupled with the power converting unit.

2. The power supply device of claim 1, wherein the power connecting unit is a two-pin plug, a three-pin plug, or a car charger adapter.

3. The power supply device of claim 1, wherein the power connecting unit has a receiving part, the power converting unit has a locking part, and the power connecting unit and the power converting unit are coupled as the receiving part is connected to the locking part.

4. The power supply device of claim 1, wherein the first connecting part has a plurality of contact elements, the second connecting part has a plurality of contact parts corresponding to the contact elements, and the contact elements contact against the corresponding contact parts.

5. The power supply device of claim 1, wherein the power converting unit has a locking slot, the function unit has a locking rail, and the locking slot is coupled with the locking rail.

6. The power supply device of claim 1, wherein the power converting unit is an AC/DC power converting element or a DC/DC power converting element.

7. The power supply device of claim 1, wherein the functional unit of the power functional module comprises one or any combinations of a DC voltage output element, a rechargeable battery, an USB connector, a light-emitting element, a stun rod and a DC fan.

8. The power supply device of claim 1, wherein when the functional unit is a rechargeable battery, the functional unit further has a third connecting part.

9. The power supply device of claim 8, wherein the third connecting part comprises a plurality of contact elements.
